(19) United States
(12) Patent Application Publication
(10) Pub. No.: US 2024/0087660 A1
(43) Pub. Date: Mar. 14, 2024

(54) OTP MEMORY DEVICE, METHOD FOR OPERATING SAME AND METHOD FOR FABRICATING SAME

(71) Applicant: HeFeChip Corporation Limited, Hong Kong (CN)

(72) Inventor: Geeng-Chuan CHERN, Cupertino, CA (US)

(21) Appl. No.: 17/953,717

(22) Filed: Sep. 27, 2022

(30) Foreign Application Priority Data
Sep. 8, 2022 (CN) 202211097667.9

(51) Int. Cl. G11C 17/12; H10B 20/25

(52) U.S. Cl. CPC G11C 17/12; H10B 20/25

(57) ABSTRACT

The present invention relates to an OTP memory device, a method for operating the OTP memory device and a method for fabricating the OTP memory device. In the OTP memory device, a PN junction is formed between a source-side LDD region and a source region in each OTP memory cell. During programming of the OTP memory cell, the PN junction is broken down, providing one-time programmability. Moreover, its circuit layout is simple, helping to achieve a reduced chip area and lower cost. In the method for fabricating the OTP memory device, OTP memory cells in the OTP memory device and MOS transistors are simultaneously formed on surface regions of a semiconductor substrate, reducing fabrication complexity and cost of the OTP memory device and making it suitable for mass production.

### CROSS-REFERENCE TO RELATED APPLICATION

This application claims the priority of Chinese patent application number 202211097667.9, filed on Sep. 8, 2022, the entire contents of which are incorporated herein by reference.

### TECHNICAL FIELD

The present invention relates to the field of semiconductor technology and, in particular, to a one-time programmable (OTP) memory device, a method for operating the OTP memory device and a method for fabricating the OTP memory device.

### BACKGROUND

One-time programmable (OTP) memory technology has been used in post-silicon validation, memory repair, online field testing, secure information storage and other applications. For example, in a memory repair application, an address of a defective cell may be recorded in an OTP memory element, and when an externally provided address is found to be the same as the address of the defective cell, a semiconductor circuit may access a redundant memory cell rather than the defective one, thus achieving the purpose of repair. As another example, in order to address security threats to Internet of Things (IoT) devices, such as information leakage, unauthorized access, malware attacks or the like, information may be stored in OTP memory elements that cannot be re-programmed.

Programming of a typical OTP memory element is accomplished by an antifuse which remains non-conductive until the element is programmed. In existing integrated circuits, an antifuse is typically constructed from two conductors and a thin dielectric layer sandwiched between them. During programming, the dielectric layer is broken down by a high voltage applied between the two conductors. There is another type of antifuse, which is a PN junction formed by doping of polysilicon. During programming, the PN junction is broken down by a reverse voltage.

However, existing OTP memory elements suffer from the problems of large overall chip area and high cost as they require complex layouts and circuits.

### SUMMARY OF THE INVENTION

The present invention provides an OTP memory device including OTP memory cells having a circuit layout, which helps to achieve a reduced chip area and lower cost, compared with the existing OTP memory elements. The present invention also provides a method for operating the OTP memory device and a method for fabricating the OTP memory device.

In one aspect, the present invention provides an OTP memory device including at least one OTP memory cell, wherein each OTP memory cell includes:
a source region, a drain region and a channel region, which are all formed in a region of a first doping type in a semiconductor substrate, wherein: the source region has the first doping type; the drain region has a second doping type; and the channel region is located between the source region and the drain region;
a source-side LDD region and a drain-side LDD region each having the second doping type, wherein the source-side LDD region and the drain-side LDD region are located on opposite sides of the channel region and are adjacent to and in contact with the source region and the drain region, respectively, wherein a PN junction is formed between the source-side LDD region and the source region; and
a gate oxide layer and a gate, which are stacked over the channel region.

Optionally, in the OTP memory device, a plurality of the OTP memory cells may form an OTP memory cell array, wherein the gates in the OTP memory cells are connected to form a plurality of word lines.

Optionally, the OTP memory cell array may include at least one pair of mirrored OTP memory cells, wherein the pair of mirrored OTP memory cells shares a common source region.

Optionally, the OTP memory device may further include:
an interlayer dielectric layer covering the OTP memory cells; and
a plurality of bit lines located on the interlayer dielectric layer, wherein the plurality of bit lines are connected to the drain regions in the OTP memory cells by contact plugs extending through the interlayer dielectric layer.

In another aspect, the present invention provides a method for operating the OTP memory device as defined above, including a one-time programming operation performed on an OTP memory cell in the OTP memory device, wherein the one-time programming operation includes:
grounding the source region in the OTP memory cell; applying a voltage higher than a breakdown voltage of the PN junction to the drain region and applying a voltage higher than a threshold voltage to the gate, wherein the voltage applied to the drain region is coupled to the source-side LDD region via the channel region and thus causes a reverse breakdown of the PN junction.

Optionally, the method may further include a reading operation performed on the OTP memory cell, wherein the reading operation includes:
grounding the source region in the OTP memory cell; applying a voltage lower than the breakdown voltage of the PN junction to the drain region; and applying a voltage higher than the threshold voltage to the gate, wherein in an event of the PN junction having been broken down during the programming of the OTP memory cell, a cell current is formed flowing from the drain region to the semiconductor substrate through the drain-side LDD region, the channel region, the PN junction that has been broken down and the source region, and wherein a presence of the cell current is detectable to determine the OTP memory cell has been programmed.

In a further aspect, the present invention provides a method for fabricating the OTP memory device as defined above, including:
providing a semiconductor substrate, which has a first region of the first doping type and a second region of the second doping type covered by a stack of a gate dielectric layer and a gate material layer;
etching the gate material layer to form a first gate over the first region and a second gate over the first region and/or the second region;
performing an LDD implantation of the second doping type on a portion of the first region located on opposite sides of the first gate and performing an LDD implantation of the first doping type on a portion of the second region and/or performing an LDD implantation of the second doping type on a portion of the first region located on opposite sides of the second gate;
forming spacers on opposite sides of the first and second gates;
performing a source/drain implantation of the second doping type on a portion of the first region on a first side of the first gate and performing a source/drain implantation of the first doping type on a portion of the first region on a second side of the first gate, and performing a source/drain implantation of the second doping type on a portion of the first region and/or performing a source/drain implantation of the first doping type on a portion of the second region on opposite sides of the second gate; and
performing an annealing to form the OTP memory cell on a surface of the first region, and at least one MOS transistor may be formed on the surface of the first and/or second region, wherein the OTP memory cell includes: the first gate, a drain region and a drain-side LDD region of the second doping type formed on the first side of the first gate, and a source region of the first doping type and a source-side LDD region of the second doping type on the second side of the first gate, wherein the MOS transistor comprises a second gate, and a source/drain region and an LDD region of the first doping type or of the second doping type on opposite sides of the second gate.

Optionally, the LDD implantation of the second doping type may be an N-type implantation performed at a dose ranging from 1E13 cm⁻² to 5E14 cm⁻² with an energy ranging from 15 KeV to 40 KeV, wherein the LDD implantation of the first doping type is a P-type implantation performed at a dose ranging from 1E13 cm⁻² to 5E14 cm⁻² with an energy ranging from 10 KeV to 30 KeV.

Optionally, the source/drain implantation of the second doping type may be an N-type implantation performed at a dose ranging from 2E15 cm⁻² to 8E15 cm⁻² with an energy ranging from 20 KeV to 50 KeV, wherein the source/drain implantation of the first doping type is a P-type implantation performed at a dose ranging from 1E15 cm⁻² to 6E15 cm⁻² with an energy ranging from 15 KeV to 50 KeV.

Optionally, the method may further include:
forming a metal silicide layer on top a surface of the first gate, a top surface of the second gate, a top surface of the source and drain regions on opposite sides of the first gates and a top surface of the source/drain regions on opposite sides of the second gates;
forming an interlayer dielectric layer covering the OTP memory cell and the MOS transistor; and
forming a bit line electrically connected to the drain region in the OTP memory cell by a contact plug extending through the interlayer dielectric layer.

In the OTP memory device and the method for operating the OTP memory device of the present invention, a PN junction is formed between the source-side LDD region and the source region in each OTP memory cell. During programming of the OTP memory cell, the PN junction is broken down, thus providing one-time programmability. Moreover, its circuit layout is simple, helping to achieve a reduced chip area and lower cost. In the method for fabricating the OTP memory device of the present invention, the OTP memory cells in the OTP memory device and the MOS transistors are simultaneously formed on the surface of the semiconductor substrate, reducing fabrication complexity and cost of the OTP memory device and making it suitable for mass production.

### BRIEF DESCRIPTION OF THE DRAWINGS

FIG. 1 is a schematic cross-sectional view of an OTP memory cell in an OTP memory device according to an embodiment of the present invention.

FIG. 2 is a schematic circuit diagram of an OTP memory cell array in an OTP memory device according to an embodiment of the present invention.

FIG. 3 is a schematic plan view of the OTP memory cell array of FIG. 2.

FIGS. 4 to 11 are schematic cross-sectional views of OTP memory cells and MOS transistors being fabricated in a method according to an embodiment of the present invention.

### DETAILED DESCRIPTION

OTP memory devices, as well as operation and fabrication thereof, according to particular embodiments of the present invention will be described in greater detail below with reference to the accompanying drawings. Note that the figures are provided in a very simplified form not necessarily drawn to exact scale and for the only purpose of facilitating easy and clear description of the embodiments. Additionally, the spatially relative terms are intended to encompass different orientations of the device in use or operation in addition to the orientation depicted in the figures. For example, if the device in the figures is inverted or otherwise oriented (e.g., rotated), the exemplary term “over” can encompass an orientation of “under” and other orientations. Throughout the drawings, if any component is identical to a labeled one, although such components may be easily identifiable in all the figures, in order for a more clear description of labels to be obtained, not all identical components are labeled and described in the following description and accompanying drawings.

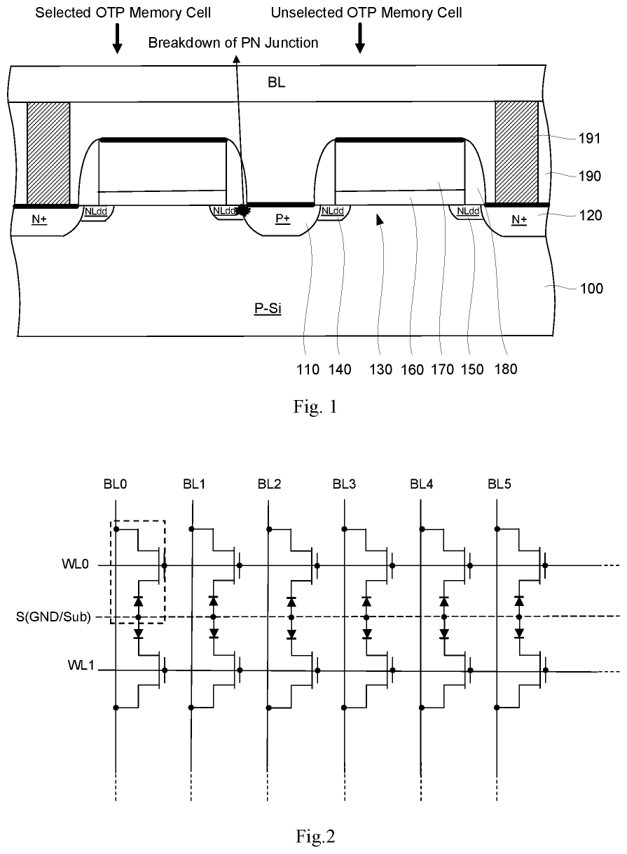

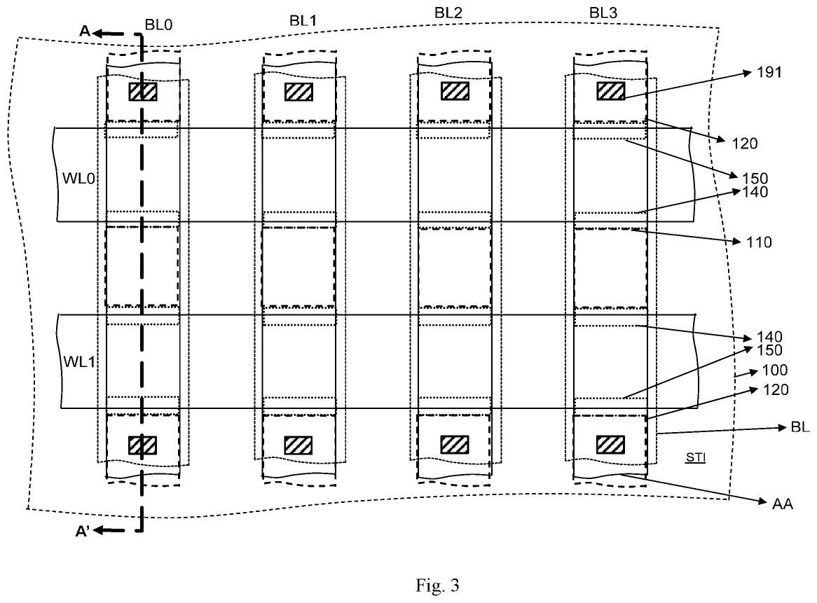

Embodiments of the present invention relate to an OTP memory device including at least one OTP memory cell, as described in the following embodiments and shown in the cross-sectional view of FIG. 1. A plurality of the OTP memory cells can make up an OTP memory cell array as shown in FIGS. 2 and 3 (the dotted box in FIG. 2 indicates one of the OTP memory cells). The cross-sectional view of FIG. 1 is taken along line A-A′ traversing an active area (AA) in FIG. 3. The OTP memory cell array may include at least one pair of mirrored OTP memory cells.

It is to be noted that the OTP memory cells according to embodiments of the present invention may be an N- or P-channel device depending on the type of mobile ions in its channel region. When the OTP memory cells are N-channel devices, the first doping type mentioned below is P-type and the second doping type is N-type. It will be understood that the present invention is also applicable to P-channel devices by changing the first doping type from P-type to N-type, and by changing the second doping type from N-type to P-type. The following embodiments are set forth mainly in the context of the OTP memory cells being N-channel devices.

Referring to FIG. 1, each of the OTP memory cells includes, all formed in a region of a first doping type (e.g., a P-type doped region) in the semiconductor substrate 100, a source region 110, a drain region 120, a channel region 130, a source-side lightly doped drain (LDD) region 140 and a drain-side LDD region 150, and a gate oxide layer 160 and a gate 170 formed over the channel region 130. The source region 110 has the first doping type, and the drain region 120 has a second doping type opposite to the first doping type. The channel region 130 is located between the source region 110 and the drain region 120. Both the source-side LDD region 140 and the drain-side LDD region 150 have the second doping type, and are located on opposite sides of the channel region 130 so as to be respectively adjacent to the source region 110 and the drain region 120. Each paired of mirrored OTP memory cells may share a common source region 110. Each of the OTP memory cells may further include spacers 180 covering opposite sides of the gate oxide layer 160 and the gate 170.

In the present embodiment, the semiconductor substrate 100 may be, for example, a P-type silicon substrate (P—Si). Moreover, the first doping type is P type (provided by a dopant such as boron, boron difluoride or indium), and the second doping type is N type (provided by a dopant such as phosphorus or arsenic). The source region 110 is P-type heavily doped (P+), and the drain region 120 is N-type heavily doped (n+). Both the source-side LDD region 140 and the drain-side LDD region 150 are N-type light doped (NLDD). The region of the first doping type may be provided either by the semiconductor substrate 100, or by doped well in the semiconductor substrate 100. Here, the region of the first doping type is a region of the P-type silicon substrate. In other embodiments, the semiconductor substrate 100 may be an N-type silicon substrate. In this case, the region of the first doping type may be a P-type doped well in the N-type silicon substrate.

Referring to FIGS. 1 to 3, the OTP memory device may include a plurality of the OTP memory cells, which are arranged into an OTP memory cell array, in which the gates 170 of the OTP memory cells may be so connected as to form a plurality of word lines (WLs, e.g., WL0, WL1, . . . in FIGS. 2 and 3). The OTP memory device may further include an interlayer dielectric layer 190 covering all the OTP memory cells and a plurality of bit lines (BLs, e.g., BL0, BL1, BL2, BL3, BL4, BL5, . . . in FIGS. 2 and 3) located on the interlayer dielectric layer 190. These bit lines may be connected to the drain regions 120 in the individual OTP memory cells in the OTP memory cell array by contact plugs 191 formed in the interlayer dielectric layer 190. The drain regions 120 of each pair of mirrored OTP memory cells may be, for example, connected to the same bit line.

In the OTP memory device, the source regions 110 of the OTP memory cells have the first doping type (e.g., P type), and the drain regions 120, the source-side LDD regions 140 and the drain-side LDD regions 150 have the second doping type (e.g., N type). Thus, PN junctions are formed between the source regions 110 and the source-side LDD regions 140. Each PN junction can be broken down during programming of the respective OTP memory cell, providing one-time programmability.

An embodiment of the present invention also relates to a method for operating the OTP memory device as defined above, which includes a one-time programming operation performed on an OTP memory cell in the OTP memory device. For the OTP memory cell array, the specific OTP memory cell to be operated may be selected by applied predefined biasing conditions to associated word and bit lines. During programming or reading of the selected OTP memory cell, the source region 110 of an associated unselected OTP memory cell and a word line associated therewith may be, for example, grounded (0 V), while an associated bit line may be, for example, set to 0 V or floated.

As an example, consider the pair of mirrored OTP memory cells shown in FIG. 1, in which the OTP memory cell on the left is selected, while the OTP memory cell on the right is not selected. Here, the selected OTP memory cell is an N-channel device with a PN junction formed between the P+ doped source region 110 and the N-doped source-side LDD region 140.

Table 1 presents biasing conditions for a one-time programming operation applied on the selected OTP memory cell according to an embodiment of the present invention. Referring to Table 1, the one-time programming operation includes: grounding the source region 110 in the selected OTP memory cell via the semiconductor substrate 100 (because of the same doping type of the source region 110 and the substrate) (S(GND/Sub) in FIG. 2); applying a voltage exceeding the breakdown voltage of the PN junction (e.g., 3-10 V) to the drain region 120 via the associated bit line; and activation of the channel between the drain region 120 and the source region 110 by applying a preset voltage (e.g., 3-10 V, higher than a threshold voltage) to the gate 170 via the associated word line. As a result, the voltage on the drain region 120 is coupled to the source-side LDD region 140 via the channel region 130, resulting in a reverse voltage present at the PN junction, which exceeds the breakdown voltage thereof and permanently breaks down the junction (“Breakdown of PN Junction” in FIG. 1), accompanied by the formation of a large reverse junction leakage current.

TABLE 1
Biasing Conditions for One-Time Programming

| Terminal | Bias |
|---|---|
| Selected WL | 3 V to 10 V |
| Unselected WL | 0 V |
| Selected BL | 3 V to 10 V |
| Unselected BL | 0 V or floating |
| P-Type silicon substrate | 0 V |

TABLE 2
Biasing Conditions for Reading

| Terminal | Bias |
|---|---|
| Selected WL | 1 V to 3 V |
| Unselected WL | 0 V |
| Selected BL | 0.5 V to 1.5 V |
| Unselected BL | 0 V or floating |
| P-type silicon substrate | 0 V |

According to this embodiment, the operating method further includes a reading operation on the selected OTP memory cell. Table 2 summarizes biasing conditions for the reading operation on the selected OTP memory cell according to an embodiment of the present invention. Referring to Table 2, the reading operation includes: grounding the source region 110 in the selected OTP memory cell via the semiconductor substrate 100; applying a voltage lower than the breakdown voltage of the PN junction (e.g., 0.5-1.5 V) to the drain region 120 via the associated bit line; and activation of the channel between the drain region 120 and the source region 110 by applying a preset voltage (e.g., 1-3 V, higher than the threshold voltage) to the gate 170 via the associated word line. In case of the PN junction in the selected OTP memory cell having been broken down during programming thereof, there will be a cell current flowing from the drain region 120 to the semiconductor substrate 100 through the drain-side LDD region 150, the channel region 130, the PN junction that has been broken down and the source region 110. However, in case of the selected OTP memory cell having not been programmed and therefore the PN junction therein having not been broken down, there will be not cell current created as blocked by the PN junction. Therefore, it can be determined whether the selected the OTP memory cell has been programmed by detecting the presence of the cell current therein. If the cell current is detected, it is determined that the OTP memory cell is in a programmed state (State “1”). Otherwise, if no such cell current is detected, it is determined that the selected OTP memory cell is in a non-programmed state (State “0”).

The OTP memory device as defined above has a simple circuit layout, which helps to achieve a reduced chip area and a lower cost.

An embodiment of the present invention further provides a method for fabricating the OTP memory device as defined above, in which the OTP memory cells in the OTP memory device and MOS transistors are formed simultaneously on a surface of the semiconductor substrate. The fabrication of the OTP memory cells is compatible with CMOS processes, helping to reduce fabrication complexity and cost of the OTP memory device and facilitating its mass production. Specifically, the method may include the processes as detailed below.

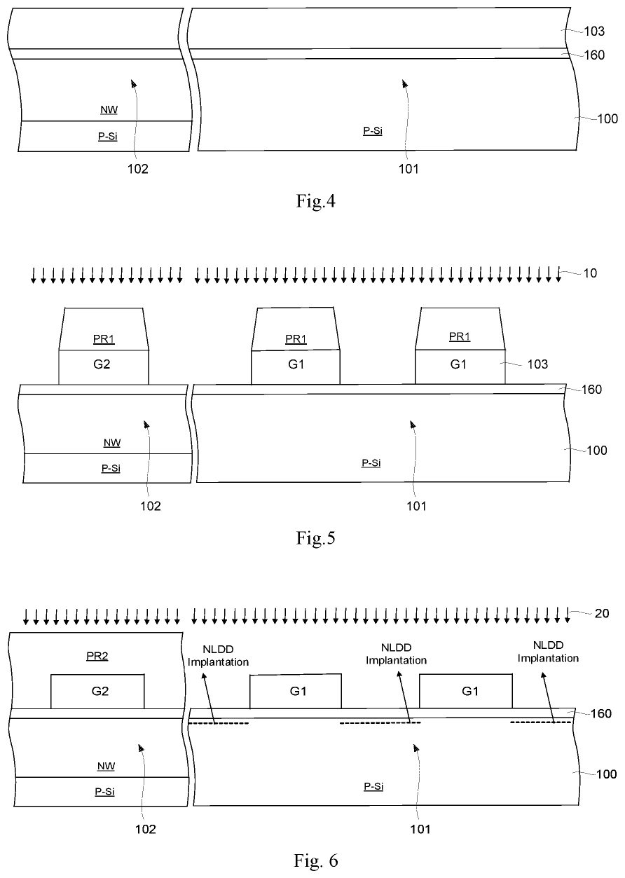

Referring to FIG. 4, first of all, a semiconductor substrate 100 is provided, which has regions 101 of a first doping type and regions 102 of a second doping type, and a gate oxide layer 160 and a gate material layer 103 are stacked over the regions 101 of the first doping type and the regions 102 of the second doping type. In this embodiment, the first doping type is P-type, and the regions 101 of the first doping type are provided for an N-channel device (e.g., an NMOS transistor, an N-channel OTP memory cell or the like; here, an N-channel OTP memory cell, as an example) to be formed therein. Additionally, the second doping type is N type, and the regions 102 of the second doping type are provided for a P-channel device (e.g., a PMOS transistor, a P-channel OTP memory cell or the like; here, a PMOS transistor, as an example) to be formed therein. Either of the regions 101 of the first doping type and the regions 102 of the second doping type may be provided by the semiconductor substrate 100, with the other being provided by doped wells in the semiconductor substrate 100. Alternatively, both may be provided by doped wells of different types in the semiconductor substrate 100. As an example, the first semiconductor substrate 100 is a P-type silicon substrate (P—Si), the regions 101 of the first doping type are regions of the P-type silicon substrate extending up to a top surface of the substrate, and the regions 102 of the second doping type are N-type doped wells (NW) in the P-type silicon substrate.

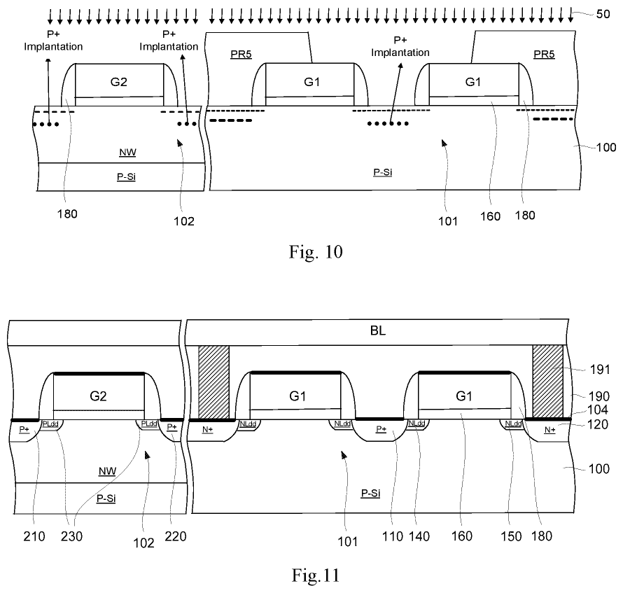

The gate oxide layer 160 may include silica (SiO₂), silicon oxynitride (SiON), hafnium oxide (HfO) or another suitable material and have a thickness of approximately 2-20 nm. The gate material layer 103 may include a doped polysilicon, a silicide, a metal or another suitable material and have a thickness of approximately 80-150 nm, wherein the gate material layer 103 may comprise an N-type doped polysilicon over regions 101 and a P-type doped polysilicon over regions 102. In another embodiment, the gate material layer 103 may comprise an N-type doped polysilicon over regions 101 and an undoped polysilicon over regions 102, wherein please further refer to FIG. 10, the undoped polysilicon over regions 102 may form P-type doped polysilicon after the completion of the source/drain implantation 50. Before proceeding to any subsequent step, it may be considered that the semiconductor substrate 100 has undergone process steps including, but not limited to, the formation of trench isolation structures (e.g., the shallow trench isolation (STI) structures in FIG. 3) in the semiconductor substrate 100, selective well implantation (e.g., the N- or P-type doped wells) and other ion implantations (e.g., for threshold voltage adjustment) and annealing.

Referring to FIG. 5, subsequently, first gates G1 over the regions 101 of the first doping type and second gates G2 over the regions 101 of the first doping type and/or over the regions 102 of the second doping type are formed by etching the gate material layer 103 using an etching process 10 with a patterned photoresist layer PR1 serving as a mask. As shown in FIG. 5, the second gates G2 formed over the regions 102 of the second doping type are illustrated. The photoresist layer PR1 is then removed.

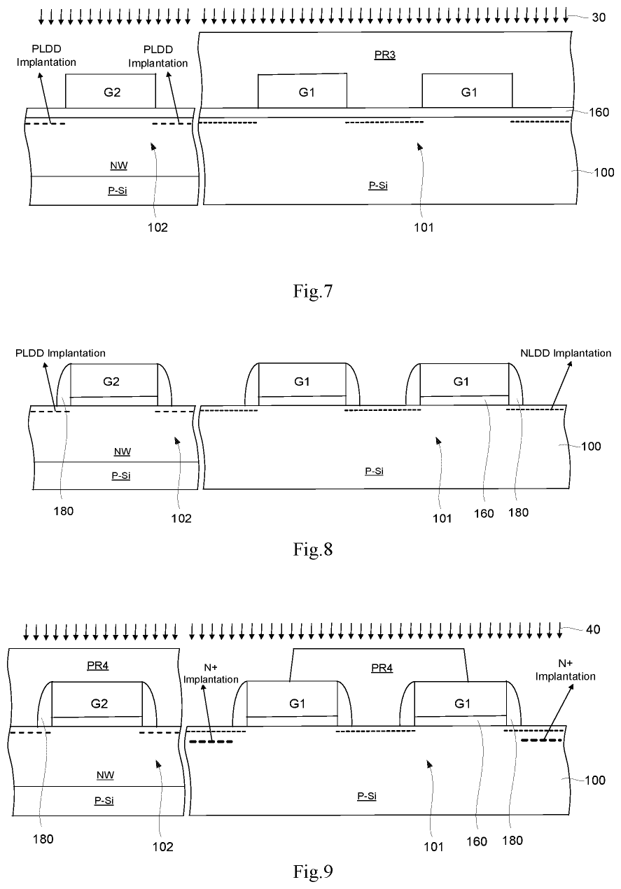

Referring to FIG. 6, after that, with a patterned photoresist layer PR2 serving a mask, an LDD implantation 20 of the second doping type is performed on portions of the regions 101 of the first doping type on opposite sides of the first gates G1. Here, the LDD implantation is an N-type LDD implantation of phosphorus or arsenic at a dose of 1E13 cm⁻²-5E14 cm⁻² performed at the locations as indicated by “NLDD Implantation” in FIG. 6 with energy of 15 KeV-40 KeV. The photoresist layer PR2 is then removed. When the second gates G2 are also formed over the regions 101 of the first doping type, an LDD implantation 20 of the second doping type may be performed on portions of the regions 101 of the first doping type located on opposite sides of the second gates at the same time. Referring to FIG. 7, afterwards, with a patterned photoresist layer PR3 serving a mask, an LDD implantation 30 of the first doping type is performed on portions of the regions 102 of the second doping type on opposite sides of the second gates G2. Here, the LDD implantation is a P-type LDD implantation of boron or boron difluoride at a dose of 1E13 cm⁻²-5E14 cm⁻² performed at the locations as indicated by “PLDD implantation” in FIG. 7 with energy of 10 KeV-30 KeV. The photoresist layer PR3 is then removed.

In this embodiment, during the aforementioned LDD implantation 20 of the second doping type and LDD implantation 30 of the first doping type, there are portions of the gate oxide layer 160 on the surface of the semiconductor substrate 100, which are not covered by the first gates G1 and the second gates G2. In an alternative embodiment, these portions of the gate oxide layer 160 not covered by the first gates G1 and the second gates G2 may be removed before the aforementioned LDD implantation 20 of the second doping type and LDD implantation 30 of the first doping type are performed.

Referring to FIG. 8, after the portions of the gate oxide layer 160 not covered by the first gates G1 and the second gates G2 are removed, spacers 180 are formed on opposite sides of the first gates G1 and second gates G2. The spacers 180 also cover opposite sides of the remaining portions of the gate oxide layer 160 under the first gates G1 and the second gates G2. The spacers 180 may include silica, silicon nitride or silicon oxynitride, or a combination thereof.

Referring to FIG. 9, with a patterned photoresist layer PR4 serving as a mask, a source/drain implantation 40 of the second doping type is performed on portions of the regions 101 of the first doping type on one side of the first gates G1. Here, N-type ions at a dose of 2E15 cm⁻²-8E15 cm⁻² are implanted at locations indicated as “N+ Implantation” in FIG. 9 with energy of 20 KeV-50 KeV. The photoresist layer PR4 is then removed. In this embodiment, at least one pair of mirrored first gates G1 is formed on the regions 101 of the first doping type, and the source/drain implantation 40 of the second doping type is performed on portions the regions 101 of the first doping type located on one side of each of the mirrored first gates G1. Here, the N-type implantation may be carried out concurrently with a source/drain implantation in a CMOS process for forming source and drain regions in the NMOS transistors. For example, when the second gates G2 are also formed over the regions 101 of the first doping type, an LDD implantation 40 of the second doping type may be performed on portions of the regions 101 of the first doping type located on opposite sides of the second gates at the same time. Referring to FIG. 10, with a patterned photoresist layer PR5 serving as a mask, a source/drain implantation 50 of the first doping type is performed on portions of the regions 101 of the first doping type located on the other side of the first gates G1 and on portions of the regions 102 of the second doping type located on opposite sides of the second gates G2. Here, P-type ions at a dose of 1E15 cm⁻²-6E15 cm⁻² are implanted at locations indicated as “P+ Implantation” in FIG. 10 with energy of 15 KeV-50 KeV. The P-type implantation may be carried out concurrently with a source/drain implantation in a CMOS process for forming source and drain regions in the PMOS transistors. The photoresist layer PR5 is then removed. As shown in FIG. 10, the source/drain implantation 50 of the first doping type is performed on portions of the regions 101 of the first doping type located on the other sides of the mirrored first gates G1. After the completion of the source/drain implantation 50 of the first doping type, an annealing process may be carried out to activate ions implanted into the regions 101 of the first doping type and the regions 102 of the second doping type during the above described ion implantation processes.

As shown in FIG. 11, as a result of the above steps, OTP memory cells are formed on the surface of the regions 101 of the first doping type, each including a first gate G1 (which may be implemented as the gate 170 in FIG. 1), a drain region 120 and a drain-side LDD region 150 of the second doping type on one side of the first gate G1, and a source region 110 of the first doping type and a source-side LDD region 140 of the second doping type on the other side of the first gate G1. In the OTP memory cell, as the source region 110 and the source-side LDD region 140 are of the opposite doping polarities, a PN junction is formed therebetween, which is broken down during programming of the OTP memory cell, thus providing one-time programmability. At the same time as the formation of the OTP memory cells, at least one MOS transistor is formed over a surface of the regions 101 of the first doping type and/or over surface of the regions 102 of the second doping type. For a specific MOS transistor, it comprises a second gate, and a source/drain region and an LDD region of the first doping type or of the second doping type formed on opposite sides of the second gate.

As shown in FIG. 11, the OTP memory cells and the MOS transistors are formed on the surface of the regions 101 of the first doping type and the surface of the regions 102 of the second doping type in the semiconductor substrate 100, respectively. In FIG. 11, it shows that MOS transistors are formed on the surface of the regions 102 of the second doping type, each including a second gate G2 and source/drain regions (including a first source/drain region 210 and a second source/drain region 220) and LDD regions 230 of the first doping type formed on opposite sides of the second gate G2.

In this embodiment, as an example, the regions of the first doping type are P-type doped regions, and the OTP memory cells are N-channel devices. In addition, the regions 102 of the second doping type are N-type doped regions, and the MOS transistors are PMOS transistors formed over the regions 102 of the second doping type. In another embodiment, the MOS transistors may be formed on the surface of the regions 101 to form a NMOS transistor. Further, NMOS and PMOS transistors may be separately formed on the surface of the regions 101 and the regions 102 at the same time. It would be appreciated that more than two such OTP memory cells and more than two such MOS transistors may be simultaneously formed on the semiconductor substrate 100. NMOS transistors and P-channel OTP memory cells may also be simultaneously formed on the semiconductor substrate 100.

Referring to FIG. 11, in this embodiment, the method may further include: forming a metal silicide layer 104 on top surfaces of the first and second gates G1, G2, the top surface of the source and drain regions 110, 120 on opposite sides of the first gate G1 and the top surface of the source/drain regions on opposite sides of the second gates G2; then forming an interlayer dielectric layer 190 over the OTP memory cells and the MOS transistors, and contact plugs 191 in the interlayer dielectric layer 190; and then forming a metal layer on the interlayer dielectric layer 190 and etching the metal layer to form therein at least one bit line (BL) electrically connected to the drain regions 120 in the OTP memory cells by the contact plugs 191.

In this method, the OTP memory cells in the OTP memory device and the MOS transistors are simultaneously formed on the surface of the semiconductor substrate 100, resulting in reduced fabrication complexity and cost of the OTP memory device and thereby making it suitable for mass production.

It is to be noted that the embodiments disclosed herein are described in a progressive manner, with the description of each embodiment focusing on its differences from others. Reference can be made between the embodiments for their identical or similar parts.

The foregoing description is merely that of several preferred embodiments of the present invention and is not intended to limit the scope of the claims of the invention in any way. Any person of skill in the art may make various possible variations and changes to the disclosed embodiments in light of the methodologies and teachings disclosed hereinabove, without departing from the spirit and scope of the invention. Accordingly, any and all such simple variations, equivalent alternatives and modifications made to the foregoing embodiments based on the essence of the present invention without departing from the scope of the embodiments are intended to fall within the scope of protection of the invention.

1. A one-time programmable (OTP) memory device comprising at least one OTP memory cell, wherein each OTP memory cell comprises:
a source region, a drain region and a channel region, which are all formed in a region of a first doping type in a semiconductor substrate, wherein: the source region has the first doping type; the drain region has a second doping type; and the channel region is located between the source region and the drain region;
a source-side LDD region and a drain-side LDD region each having the second doping type, wherein the source-side LDD region and the drain-side LDD region are located on opposite sides of the channel region and are adjacent to and in contact with the source region and the drain region, respectively, wherein a PN junction is formed between the source-side LDD region and the source region; and
a gate oxide layer and a gate, which are stacked over the channel region.

2. The OTP memory device of claim 1, wherein a plurality of the OTP memory cells form an OTP memory cell array, and wherein the gates in the OTP memory cells are connected to form a plurality of word lines.

3. The OTP memory device of claim 2, wherein the OTP memory cell array comprises at least one pair of mirrored OTP memory cells, and wherein the pair of mirrored OTP memory cells shares a common source region.

4. The OTP memory device of claim 2, further comprising:
an interlayer dielectric layer covering the OTP memory cells; and
a plurality of bit lines located on the interlayer dielectric layer, wherein the plurality of bit lines are connected to the drain regions in the OTP memory cells by contact plugs extending through the interlayer dielectric layer.

5. A method for operating the OTP memory device of claim 1, comprising a one-time programming operation performed on an OTP memory cell in the OTP memory device, wherein the one-time programming operation comprises:
grounding the source region in the OTP memory cell;
applying a voltage higher than a breakdown voltage of the PN junction to the drain region; and
applying a voltage higher than a threshold voltage to the gate,
wherein the voltage applied to the drain region is coupled to the source-side LDD region via the channel region and thus causes a reverse breakdown of the PN junction.

6. The method of claim 5, further comprising a reading operation performed on the OTP memory cell, wherein the reading operation comprises:
grounding the source region in the OTP memory cell;
applying a voltage lower than the breakdown voltage of the PN junction to the drain region; and
applying a voltage higher than the threshold voltage to the gate,
wherein in an event of the PN junction having been broken down during the programming of the OTP memory cell, a cell current is formed flowing from the drain region to the semiconductor substrate through the drain-side LDD region, the channel region, the PN junction that has been broken down and the source region, and wherein a presence of the cell current is detectable to indicate that the OTP memory cell has been programmed.

7. A method for fabricating the OTP memory device of claim 1, comprising:
providing a semiconductor substrate, which has a first region of a first doping type and a second region of a second doping type covered by a stack of a gate dielectric layer and a gate material layer;
etching the gate material layer to form a first gate over the first region and a second gate over the first region and/or the second region;
performing a lightly doped drain (LDD) implantation of the second doping type on a portion of the first region located on opposite sides of the first gate, and performing an LDD implantation of the first doping type on a portion of the second region and/or performing an LDD implantation of the second doping type on a portion of the first region located on opposite sides of the second gate;
forming spacers on opposite sides of the first and second gates;
performing a source/drain implantation of the second doping type on a portion of the first region on a first side of the first gate, and performing a source/drain implantation of the first doping type on a portion of the first region on a second side of the first gate, and performing a source/drain implantation of the second doping type on a portion of the first region and/or performing a source/drain implantation of the first doping type on a portion of the second region on opposite sides of the second gate; and
performing an annealing to form the OTP memory cell on a surface of the first region, and at least one MOS transistor is formed on a surface of the first and/or second region, wherein the OTP memory cell comprises: the first gate, a drain region and a drain-side LDD region of the second doping type formed on the first side of the first gate, and a source region of the first doping type and a source-side LDD region of the second doping type on the second side of the first gate, wherein the MOS transistor comprises a second gate, and a source/drain region and an LDD region of the first doping type or of the second doping type on opposite sides of the second gate.

8. The method of claim 7, wherein the LDD implantation of the second doping type is an N-type implantation performed at a dose ranging from 1E13 cm⁻² to 5E14 cm⁻² with an energy ranging from 15 KeV to 40 KeV, and wherein the LDD implantation of the first doping type is a P-type implantation performed at a dose ranging from 1E13 cm⁻² to 5E14 cm⁻² with an energy ranging from 10 KeV to 30 KeV.

9. The method of claim 7, wherein the source/drain implantation of the second doping type is an N-type implantation performed at a dose ranging from 2E15 cm⁻² to 8E15 cm⁻² with an energy ranging from 20 KeV to 50 KeV, and wherein the source/drain implantation of the first doping type is a P-type implantation performed at a dose ranging from 1E15 cm⁻² to 6E15 cm⁻² with an energy ranging from 15 KeV to 50 KeV.

10. The method of claim 7, further comprising:
forming a metal silicide layer on a top surface of the first gate, a top surface of the second gate, a top surface of the source and drain regions on opposite sides of the first gate and a top surface of the source/drain regions on opposite sides of the second gate;
forming an interlayer dielectric layer covering the OTP memory cell and the MOS transistor; and
forming a bit line electrically connected to the drain region in the OTP memory cell by a contact plug extending through the interlayer dielectric layer.
